(19) United States
(12) Patent Application Publication
(10) Pub. No.: US 2019/0284716 A1
(43) Pub. Date: Sep. 19, 2019

(54) APPARATUS AND METHOD OF PRODUCING DIAMOND AND PERFORMING REAL TIME IN SITU ANALYSIS

(71) Applicant: Devi Shanker Misra, Singapore (SG)

(72) Inventor: Devi Shanker Misra, Singapore (SG)

(21) Appl. No.: 16/285,116

(22) Filed: Feb. 25, 2019

Related U.S. Application Data
(63) Continuation of application No. 14/424,165, filed on Feb. 26, 2015, now abandoned.
(60) Provisional application No. 61/695,052, filed on Aug. 30, 2012.

(51) Int. Cl. C30B 25/16; H01J 37/32; C23C 16/52; C23C 16/27; C30B 25/10; C30B 29/04; C23C 16/511

(52) U.S. Cl. CPC C30B 25/16; H01J 2237/24475; C23C 16/52; C23C 16/274; C30B 25/105; H01J 37/32192; H01J 37/32935; H01J 37/3299; C30B 29/04; C23C 16/511; H01J 2237/2482; H01J 2237/24485; H01J 2237/3323; H01J 2237/2445; H01J 2237/202; H01J 2237/3321; H01J 37/32972

(57) ABSTRACT

An apparatus for producing diamond and performing real time in situ analysis, comprising: a housing, a reaction chamber, the reaction chamber being structurally connected to the housing, the reaction chamber comprising of an enclosed area adapted to house the growing of diamonds, a radiating means, the radiating means being mounted above the reaction chamber within the housing, the radiating means adapted to emit microwave into the reaction chamber to effect the growth of diamonds within the reaction chamber, a dielectric cover being provided at the top of the reaction chamber and adapted to allow the radiation wave from the radiating means to enter the reaction chamber, a recording means mounted within the annual housing and above the reaction chamber, a measuring mechanism arranged at the periphery of the reaction chamber, a microscope adjacently arranged on the outside of the reaction chamber.

### CROSS REFERENCE TO RELATED APPLICATIONS

This Continuation Application claims the benefit of U.S. application Ser. No. 14/424,165, filed on Feb. 26, 2015, which application is a 371 Application and claims the benefit of PCT/SG2013/000377 filed on Aug. 29, 2013, which claims the benefit of U.S. Provisional Application No. 61/695,052, filed on Aug. 30, 2012, which applications are incorporated herein in their entirety by this reference.

### FIELD OF THE INVENTION

This invention relates to apparatus and method of producing diamond and performing real time measurements for real time in situ analysis of the diamond growth in situ. In particularly, the invention relates to apparatus and method of producing diamonds by microwave plasma enhanced chemical vapor deposition (MPCVD) and performing real time measurements for analysis of the diamond growth in situ.

### BACKGROUND

Diamonds, such as single crystal diamonds, have potential for a wide range of scientific, industrial and commercial applications, such as gems, heat dissipation devices, semiconducting devices, optical windows, electromagnetic waveguides, particle detectors, quantum computing devices and so forth. As the commercial demand for single crystal diamonds increase over the years, it is essential to increase the production of optical and scientific grade single crystal diamonds without compromising the quality of the single crystal diamonds. However, defects, inclusions, microscopic grain boundaries, other orientations are prominent defects commonly found in single crystal diamonds which have to be characterized in details.

There exists a number of various chemical vapor deposition (CVD) device and method used to produce single crystal diamonds. For instance, microwave plasma enhanced chemical vapor deposition (MPCVD) method can be used for producing high-quality single crystal diamonds. Currently, the properties of single crystal diamond are characterized by various measuring instruments, such as microscope, spectroscopes and the like, after the completion of diamond growth. The diamond crystal structure and diamond crystal surface property can be measured by analytic techniques, such as X-ray diffraction (XRD), Reflection high-energy electron diffraction (RHEED), and the like. However, this kind of ex situ analysis could only be performed when the grown diamond is removed out from the CVD reaction chamber. Even though these measuring instruments and analytic techniques can identify defects, contaminations and inclusions in the diamonds, it is difficult to remove them in subsequent processes.

In addition, the temperature of the CVD process required for single crystal diamond growth is typically 950° C. to 1000° C. which leads to excessive heating of the quartz dome. Quartz dome is incapable of efficiently dissipating heat generated in the reaction regime during single crystal diamond growth. Thus, the temperature of the quartz dome has to be monitored at several locations to get an estimate of the average temperature, requiring plurality pyrometers at different locations. Moreover, as only air cooling is provided to the quartz dome in conventional CVD apparatus, the quartz dome cannot be efficiently cooled to control its temperature. High quartz dome temperature could cause O-ring malfunction, which results in contaminated gas leakage into reaction chamber. Ultimately, grown diamond crystal quality could be deteriorated due to the presence of contaminating gases in the reaction chamber.

U.S. Pat. No. 6,837,935 discloses a method of forming a diamond film and a film-forming apparatus. Specifically, it teaches using spectroscope to measure a spectrum of light emitted from plasma discharge. However, it does not suggest any method to perform characterization on diamond growth surface in situ.

There is a need to provide aforementioned analysis and identify the imperfection in the earlier stage. It is an objective of the present invention to provide a device and method of obtaining real-time characterization of the diamond growth surface during production processes without interrupting the production process. More particularly, characterization of the defects can be done real time in situ during diamond growth in the chamber capable of operating CVD process, such that CVD process can be optimized in time to improve the yield of high-quality diamonds.

It is another objective of the present invention to provide a way of cooling reaction regime and accurately controlling reaction chamber temperature.

Other objects and advantages of the present invention will become apparent from the following description, taken in connection with the accompanying drawings, wherein, by way of illustration and example, an embodiment of the present invention is disclosed.

### SUMMARY

In accordance with a first aspect of the present invention, there is provided an apparatus for producing diamond and performing real time in situ analysis, comprising:

a housing,

a reaction chamber, the reaction chamber being structurally connected to the housing, the reaction chamber comprising of an enclosed area adapted to house the growing of diamonds,

a radiating means, the radiating means being mounted above the reaction chamber within the housing, the radiating means adapted to emit microwave into the reaction chamber to effect the growth of diamonds within the reaction chamber,

a dielectric cover being provided at the top of the reaction chamber and adapted to allow the radiation wave from the radiating means to enter the reaction chamber.

In accordance with a second aspect of the present invention, there is provided an apparatus for producing diamond and performing real time in situ analysis, comprising:

a housing,

a reaction chamber, the reaction chamber being structurally connected to the housing, the reaction chamber comprising of an enclosed area adapted to house the growing of diamonds,

a radiating means, the radiating means being mounted above the reaction chamber within the housing, the radiating means adapted to emit microwave into the reaction chamber to effect the growth of diamonds within the reaction chamber,

a dielectric cover being provided at the top of the reaction chamber and adapted to allow the radiation wave from the radiating means to enter the reaction chamber,

a recording means mounted within the annual housing and above the reaction chamber,

a measuring mechanism arranged at the periphery of the reaction chamber, the measuring mechanism comprising of a means of emitting analytical beams and a means of receiving analytical beams,

a microscope adjacently arranged on the outside of the reaction chamber.

In accordance with a third aspect of the present invention, there is provided a method of producing diamond and, performing real time in situ analysis, comprising:

providing an apparatus according to claims 1 to 22,

placing a plurality of diamond seeds inside the reaction chamber,

supplying hydrogen gas into the reaction chamber,

directing microwave emitted from the radiating means into the reaction chamber to form plasma discharge,

supplying mixture of reaction gases into the reaction chamber,

growing the diamonds to a predetermined thickness,

measuring a set of predefined characteristics of the growth diamond layer,

performing real time in situ analysis based on the measurement result,

adjusting the process conditions according to the in situ analysis result,

growing the diamond until a desirable thickness is achieved.

Note that the various features of the present invention described above may be practiced alone or in combination. These and other features of the present invention will be described in more detail below in the detailed description of the invention and in conjunction with the following figures.

### BRIEF DESCRIPTION OF THE DRAWINGS

In order that the present invention may be more clearly ascertained, some embodiments will now be described, by way of example, with reference to the accompanying drawings, in which:

FIG. 1 illustrates a schematic of an apparatus for producing diamonds according to a first embodiment of present invention;

FIG. 2 illustrates a schematic of an apparatus for producing diamonds according to a second embodiment of present invention;

FIG. 3 shows performing the real time in situ analysis during the production of diamonds according to a first embodiment of present invention;

FIG. 4 shows the performing of performing real time in situ analysis during the production of diamonds according to other embodiment of present invention;

FIG. 5 illustrates a top view of the reaction chamber along dash line A-A in FIG. 4; and

FIG. 6 illustrates a process flow chart for a method of producing diamond and performing real time in situ analysis according to a preferred embodiment of present invention.

The Figures are diagrammatic and not drawn to scale. In the Figures, elements which correspond to elements already described have the same reference numerals.

### DETAILED DESCRIPTION

The present invention will now be described in detail with reference to several embodiments thereof as illustrated in the accompanying drawings. In the following description, numerous specific details are set forth in order to provide a thorough understanding of embodiments of the present invention. It will be apparent, however, to one skilled in the art, that embodiments may be practiced without some or all of these specific details. In other instances, well known process steps and/or structures have not been described in detail in order to not unnecessarily obscure the present invention. The features and advantages of embodiments may be better understood with reference to the drawings and discussions that follow.

Aspects, features and advantages of exemplary embodiments of the present invention will become better understood with regard to the following description in connection with the accompanying drawing(s). It should be apparent to those skilled in the art that the described embodiments of the present invention provided herein are illustrative only and not limiting, having been presented by way of example only. All features disclosed in this description may be replaced by alternative features serving the same or similar purpose, unless expressly stated otherwise. Therefore, numerous other embodiments of the modifications thereof are contemplated as falling within the scope of the present invention as defined herein and equivalents thereto. Hence, use of absolute and/or sequential terms, such as, for example, “always,” “only,” “will,” “will not,” “shall,” “shall not,” “must,” “must not,” “first,” “initially,” “next,” “subsequently,” “before,” “after,” “lastly,” and “finally,” are not meant to limit the scope of the present invention as the embodiments disclosed herein are merely exemplary.

In accordance with a first aspect of the present invention, there is provided an apparatus capable of operating chemical vapor deposition for producing diamonds. The apparatus comprises of a housing having a reaction chamber structurally connected to the housing. The reaction chamber comprise of an enclosed space adapted to house the growing of diamonds therein.

A radiating means is mounted above the reaction chamber within the housing. The radiating means is adapted to emit microwave into the reaction chamber to effect the growth of diamonds within the reaction chamber.

The top of the reaction chamber is provided with a dielectric cover adapted to allow radiation wave from the radiating means to enter into the reaction chamber and also to allow the recording means (to be described later) to record the image and video of growing the diamonds within the reaction chamber.

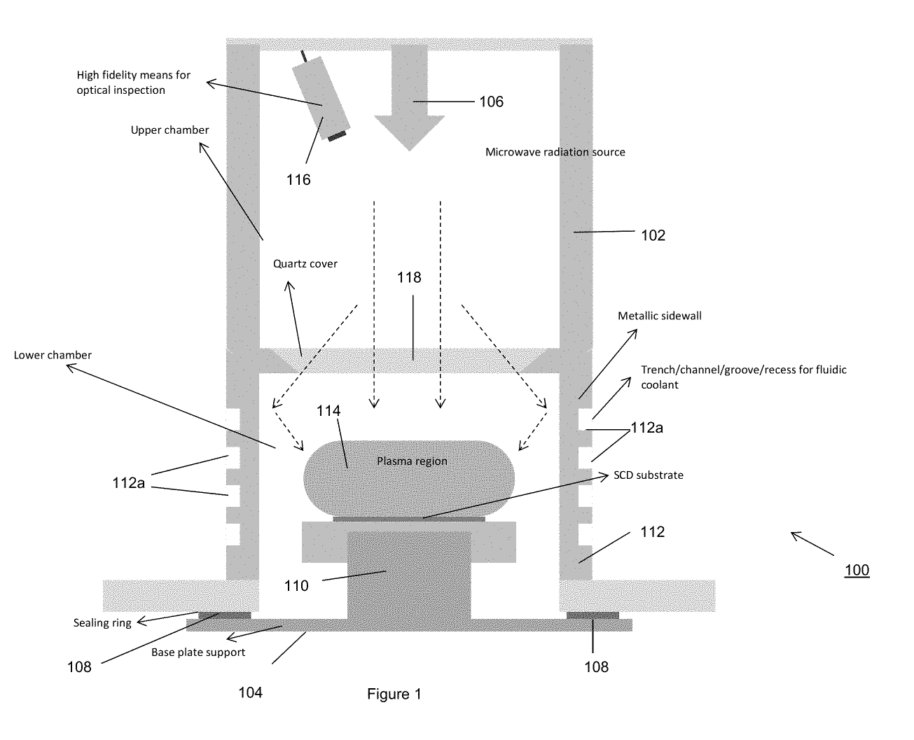

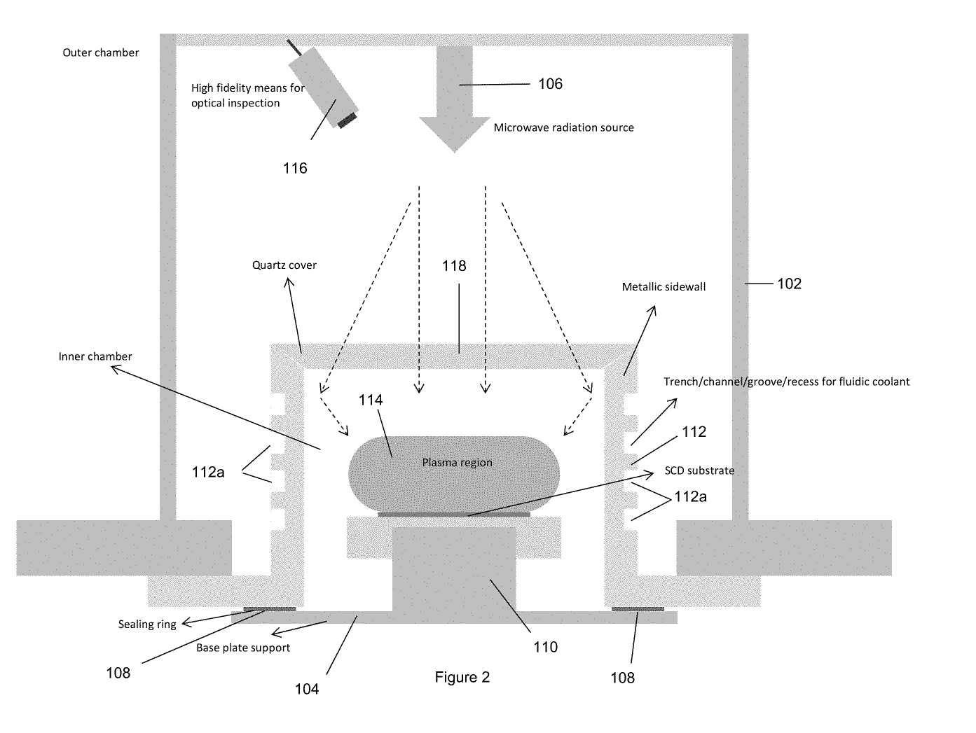

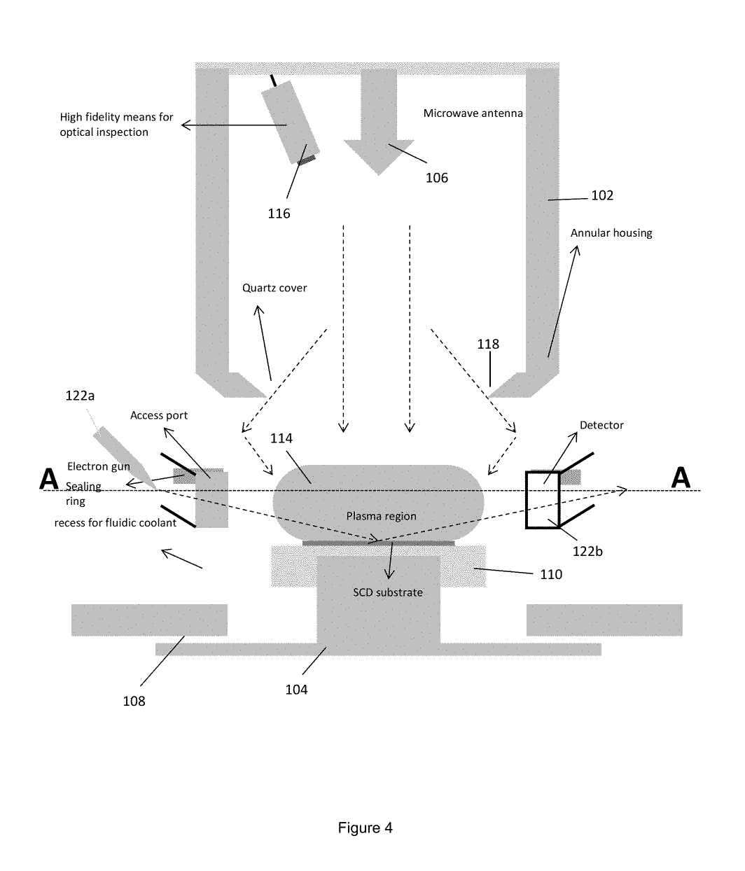

It is submitted that the general description of FIG. 1 will suffice to describe the components that are likewise named in FIGS. 2 to 4.

FIG. 1 illustrates a schematic view of an apparatus 100 capable of operating chemical vapor deposition (CVD) process in accordance with a first embodiment of the present invention. The CVD process includes microwave plasma chemical vapor deposition (MPCVD) or any other suitable CVD process. As shown, the apparatus 100 comprises of a housing 102 mounted on top of a reaction chamber 112.

FIG. 2 illustrates a schematic view of an apparatus 100 capable of operating chemical vapor deposition (CVD) process in accordance with the second embodiment of the present invention. The CVD process includes microwave plasma chemical vapor deposition (MPCVD) or any other suitable CVD process. As shown, the apparatus 100 comprises of a housing having a reaction chamber 112 mounted within the housing 102.

The housing may in the form of an annular housing 102 having a cylindrical metallic sidewall.

In the first embodiment as shown in FIG. 1, the annular housing 102 is mounted on top of the reaction chamber 112. The reaction chamber 112 is also mounted on top of a support in the form of a base plate support 104. The base plate support 104 is coupled to the reaction chamber 112 by means of a sealing ring 108, so that a vacuum environment can be created and maintained within the reaction chamber 112 during the CVD process.

In the second embodiment as shown in FIG. 2, the annular housing 102 is mounted on top of a support in the form of a base plate support 104. The reaction chamber 112 is mounted within the housing 102 such that the base plate support 104 is coupled to the reaction chamber 112 by means of a sealing ring 108, so that a vacuum environment can be created and maintained within the reaction chamber 112 during the CVD process.

It is submitted that a vacuum environment is one of the conditions for growing diamonds within the reaction chamber.

The reaction chamber 112 comprise of an enclosed space adapted to house the growth of diamonds therein. The top of the reaction chamber 112 is a dielectric cover in the form of quartz cover 118. The quartz cover 118 is adapted to allow radiation wave from the radiating means 106 to enter into the reaction chamber 112 and also to allow the recording means 116 to record the growth of the diamonds within the reaction chamber 112.

The apparatus 100 includes a radiating means in the form of microwave antenna (also known as microwave radiation source) 106. When in use, the microwave antenna 106 is coupled to the microwave waveguide (not shown) so as to transmit microwave into the reaction chamber 112 to effect the growth of diamonds within the reaction chamber 112. The microwave waveguide is provided and adapted to transmit and direct microwave into the apparatus 100 and at the same time also to prevent the microwave source from incurring damages caused by excessive reverse transmission of microwave. The microwave generator (not shown) includes a magnetizing means in the form of a magnetron is provided to produce a microwave having 6 kilowatt output power at a frequency of 2.45 GHz.

In the reaction chamber 112, a substrate stage 110 is mounted concentrically therein and is supported by the base plate support 104. When in use, a plurality of diamond seeds, are disposed on the substrate stage 110 directly or indirectly thereon. In the first and second embodiments, the diamond seeds may be placed directly on the substrate stage 110 for diamond growth. In other embodiment, the diamond may be first placed onto a molybdenum holder before the molybdenum holder is placed onto the substrate stage 110 for diamond growth.

A reaction gas inlet (not shown) is coupled to the reaction chamber 112 so as to supply a mixture of reaction gases into the reaction chamber 112. The mixture of reaction gases is selected from, but not limit to, the group of hydrocarbonaceous gas, hydrogen gas, nitrogen gas, and gases containing other dopants.

When in use, the microwave transmitted by the microwave antenna 106 enters into the reaction chamber 112 by penetrating through the quartz plate 118 and thereafter excites the mixture of reaction gases so as to form a plasma discharge 114. Under a suitable condition, diamond grows on the surface of diamond seeds in the plasma discharge 114 defining a growth surface. As described earlier, one of the conditions is a vacuum environment created and maintained within the reaction chamber 112.

A plurality of recesses 112a is integrally formed on the exterior surface of the cylindrical metallic sidewall of the reaction chamber 112a. In the first and second embodiments, fluidic coolant may be provided to flow continuously in the recesses so as to effectively remove the heat generated inside the reaction chamber 112. The fluidic coolant may be air, nitrogen, inert gas, water or combinations thereof or any other suitable coolants. In other embodiment, the fluidic coolant may be confined in a pipe positioned in the recesses. The fluidic coolant flowing in the recesses can dissipate excessive heat generated by the plasma discharge so as to maintain the temperature in the reaction chamber 112 within a suitable range, within which the sealing rings 108 are functioning effectively to maintain reaction chamber pressure and also to prevent the entrance of contaminating gases into the reaction chamber 112 during diamond growth.

Performing real time in situ analysis during the production of diamonds can be done by providing a recording means, a microscope and a measuring mechanism according to a second aspect of the present invention, which will be described more in detail as follows.

A recording means in the form of high fidelity means 116 is mounted within the annular housing 102 and above the reaction chamber 112 as shown in FIGS. 1 to 4. The high fidelity means 120 is adapted for optically inspecting the plasma discharge and the diamond growth surface during the diamond growth process. The high fidelity means includes a high fidelity camera 120 mounted at the top of the annular housing 104 so as to capture the top view of the plasma discharge 114 and the diamond growth surface. The high fidelity camera 116 is able to record both images and videos of the diamond growth surface for the purpose of studying the process of diamond growth.

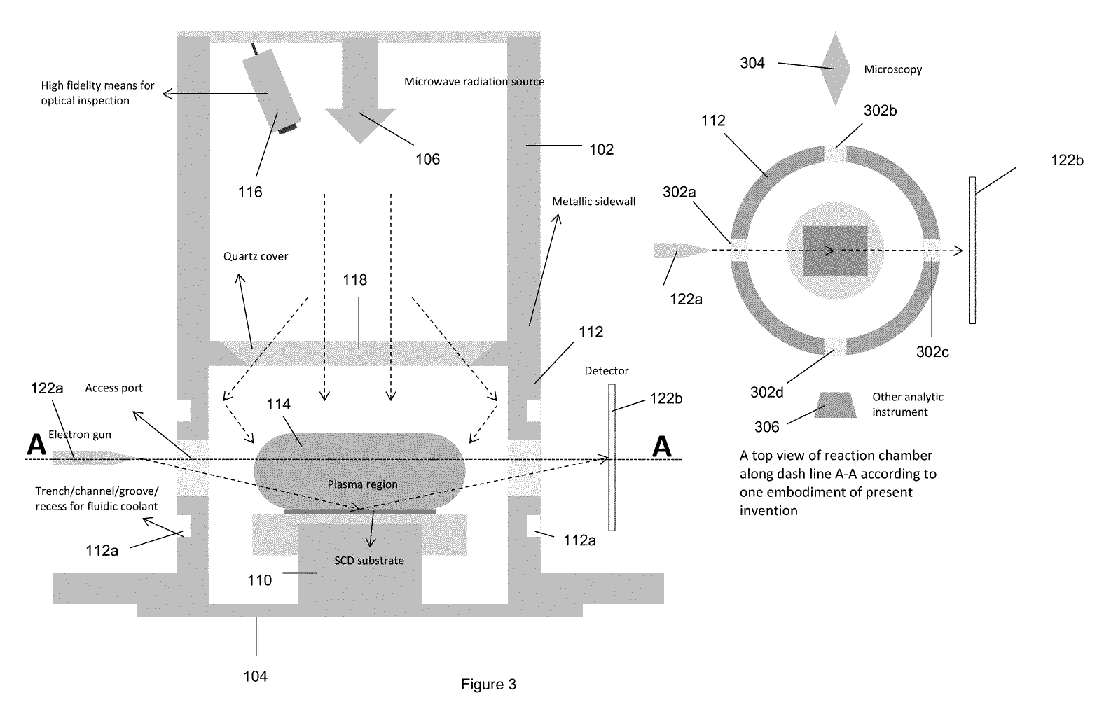

FIG. 3 illustrates a schematic view of the measuring mechanism being provided and arranged at the periphery of the reaction chamber 112 in a first embodiment of the present invention.

FIG. 3 also illustrates a top view of the reaction chamber 112 being provided with a measuring mechanism along dash line A-A. As shown in FIG. 3, a plurality of access ports (302a, 302b, 302c, 302d) is integrally formed on the cylindrical metallic sidewall of the reaction chamber 112.

A measuring mechanism is provided and mounted at the periphery of reaction chamber 112 proximate to the first and third access ports (302a, 302c). The measuring mechanism comprises of a means of emitting analytical beams 122a and a means of receiving the analytical beams 122b.

In a first embodiment of the present invention as shown in FIG. 3, the means of emitting analytical beams may be in the form of an electron gun 122a. The electron gun 122a is arranged outside of the first access port 302a to emit electron to strike the diamond growth surface. In other embodiment, the means of emitting analytical beams may be one or more instruments selected from the group of Langmuire probes, long working length microscopy, spectroscopy (photoluminescence spectroscopy, cathodoluminescence spectroscopy, Raman spectroscopy, optical spectroscopy and the like) and reflection high-energy electron diffraction (RHEED).

A means of receiving electron in the form of a detector 112b, for instance ZnS phosphor screen detector, is arranged outside of the third access port 302c that is opposite of the first access port 302a for receiving diffracted electrons.

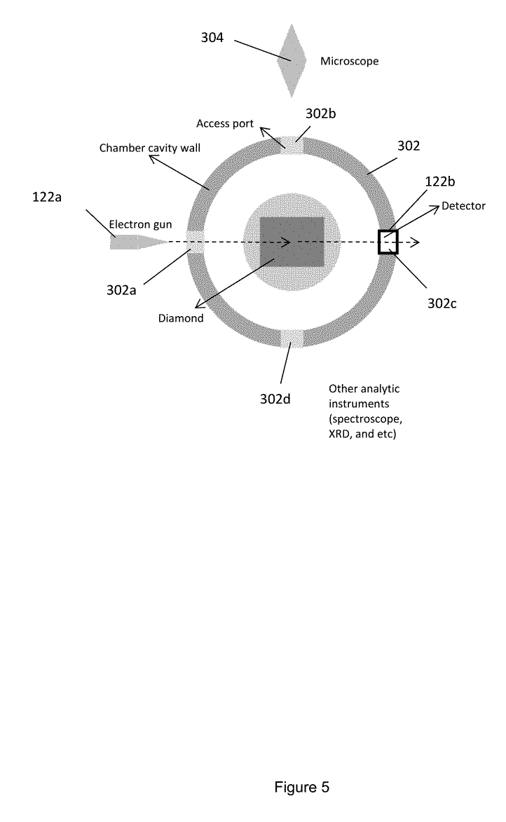

In the first embodiment as shown in FIG. 3, the detector 112b is arranged at the outer side of the cylindrical metal side wall of the reaction chamber 112. In the second embodiment as shown in FIG. 5, the detector 112b is arranged within the cylindrical metal side wall of the reaction chamber 112.

The measuring mechanism is operable to collect information about the growth surface of the diamond so that real time in situ analysis can be performed while diamond is being grown in the reaction chamber 112 at the same time. It is submitted that a real-time measurement of the diamond growth surface during diamond growth processes can be obtained such that real time in situ analysis can be performed in situ. The real-time characteristics of diamond growth surface are useful in understanding diamond growth mechanism.

FIG. 5 also illustrates a top view of the reaction chamber 112 along dash line A-A. A plurality of access ports (302a, 302b, 302c, 302d) can be formed at selected location on cylindrical metal sidewall of the reaction chamber 112. As shown in FIG. 5, there are four access ports (302a, 302b, 302c, 302d) formed on the sidewall 302 in the first and second embodiments of the present invention. In other embodiments, any other number of access ports may be formed on the cylindrical metal wall 302 depending on the real time in situ analysis to be performed.

During real time in situ analysis, the electron gun 112a emits a beam of electrons which enter into the reaction chamber 112 via one of the access ports and strike the diamond growth surface at a very small angle relative to the diamond growth surface. Incident electrons diffract from carbon atoms at the diamond growth surface, and a small fraction of the diffracted electrons interfere constructively at specific angles and form regular patterns on the detector. The electrons interfere according to the position of atoms on the diamond growth surface, so the diffraction pattern at the detector is a function of the diamond growth surface.

As shown in FIG. 3, a microscope in the form of a long working length microscope 304 is provided and adjacently arranged at the outside of second access port 302b in the first embodiment of the present invention. The microscope 304 is used to observe the plasma discharge 114 and collect the images of the diamond growth surface.

Other analytic instruments 306 may be adjacently arranged at the outside of the a fourth access port 302d that is opposite of the second access port 302b. The analytical instrument includes Raman spectroscope and XRD for measuring the purity of the grown diamond layer through the fourth access port 302d and obtain Raman spectrum based on measurement results.

In another embodiment of the present invention, a means for adjusting the position of the growth surfaces of the diamond seeds along axis of the annular housing 104 is provided in the substrate stage 110. The means of adjustment (not shown) may be an actuator, a step motor and the like. The means of adjustment is used to maintain the growth surfaces of the diamond seeds at a position, where the electron beam from the electron gun 112a can always strike on the diamond growth surface throughout the whole diamond synthetic process. After diamond growth for a specific time interval, certain thickness, x urn, of diamond has been grown. The means of adjustment brings the growth surfaces downwards along axis of the annular housing 104 for the same x urn such that electron beam can strike on the growth surfaces without any adjustment to itself. It has been unexpectedly discovered that a more accurate real time in situ analysis result can be obtained with the aforementioned method.

In accordance with a third aspect of the present invention, it provides a method of producing diamond and performing real time in situ analysis thereof

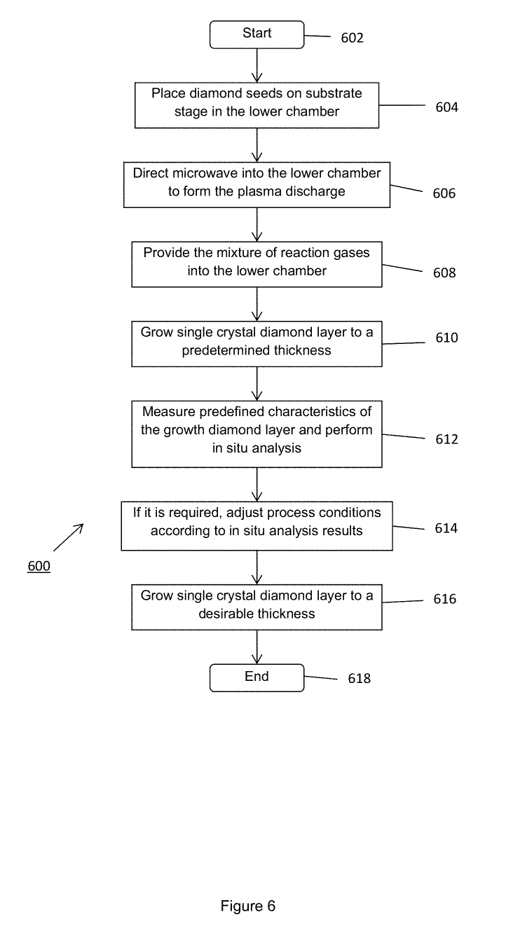

A process flow chart 600 is shown in FIG. 6 in accordance with a preferred embodiment of the present invention.

The process starts at step 602.

At step 604, a plurality of diamond seeds are disposed inside the reaction chamber 112. In the first embodiment of the present invention, the plurality of diamond seeds are disposed on a substrate stage in the reaction chamber 112. In other embodiment, diamond seeds may be disposed onto a molybdenum substrate holder first before the molybdenum substrate holder is placed on the substrate stage 110.

After that, at step 606, hydrogen gas is supplied into the reaction chamber 112 and microwave emitted from the microwave radiation source 106 is directed thereto to form plasma discharge 114 so as to treat the top surface of diamond seeds.

At step 608, the mixture of reaction gases is supplied into the reaction chamber 112, wherein the mixture of reaction gases may comprise hydrocarbonaceous gas, hydrogen gas, nitrogen gas, and gases containing other dopants.

At step 610, after a predetermined thickness diamond layer is grown on the diamond seeds in the plasma discharge, a set of predefined characteristics of the growth diamond layer are measured and real time in situ analysis is performed based on the measurement results in step 612.

If it is required, process conditions are adjusted according to in situ analysis results at step 614.

Growth of diamond layer continues until a desirable thickness is achieved at step 616.

The process ends at step 618.

While this invention has been described in terms of several embodiments, there are alterations, modifications, permutations, and substitute equivalents, which fall within the scope of this invention. Although sub-section titles may have been provided to aid in the description of the invention, these titles are merely illustrative and are not intended to limit the scope of the present invention.

It is apparent to a person skilled in the art that many modifications, alternatives and variations may be made to the preferred embodiment of the present invention as described above without departing from the spirit and scope of the present invention. Accordingly, it is intended to embrace all such modifications, alternatives and variations that fall within the scope of the included claims.

1. An apparatus for producing diamond and performing real time in situ analysis, comprising:
a housing,
a reaction chamber, the reaction chamber being structurally connected to the housing, the reaction chamber comprising of an enclosed area adapted to house the growing of diamonds,
a radiating means, the radiating means being mounted above the reaction chamber within the housing, the radiating means adapted to emit microwave into the reaction chamber to effect the growth of diamonds within the reaction chamber,
a recording means mounted within the annual housing and above the reaction chamber,
a dielectric cover being provided on top of the reaction chamber and arranged in between the enclosed area and both of the radiating means and recording means and is adapted to allow the radiation wave from the radiating means to enter the reaction chamber and also to allow the recording means to record the growth of the diamonds within the reaction chamber.

2. An apparatus for producing diamond and performing real time in situ analysis, further comprising:
a measuring mechanism arranged at the periphery of the reaction chamber, the measuring mechanism comprising of a means of emitting analytical beams and
a means of receiving analytical beams, a microscope adjacently arranged on the outside of the reaction chamber.

3. The apparatus according to claim 1, wherein the housing is mounted on top of the reaction chamber.

4. The apparatus according to claim 3, wherein the reaction chamber is mounted on top of a support, the support is coupled to the reaction chamber by means of a sealing ring.

5. The apparatus according to claim 1, wherein the reaction chamber is mounted within the housing.

6. The apparatus according to claims 5, wherein the housing is mounted on top of a support, the support is coupled to the reaction chamber by means of a sealing ring.

7. The apparatus according to claim 1, wherein the dielectric cover is in the form of quartz cover.

8. The apparatus according to claim 1, wherein the radiating means is in the form of microwave antenna.

9. The apparatus according to claim 1, wherein the reaction chamber is provided with a substrate stage mounted concentrically herein, the substrate stage is supported by the support.

10. The apparatus according to claim 4, wherein the support is in the form of base plate support.

11. The apparatus according to claim 1, wherein reaction chamber comprise of cylindrical metallic sidewall.

12. The apparatus according to claim 11, wherein a plurality of recesses being integrally formed on the exterior surface of the cylindrical metallic sidewall.

13. The apparatus according to claim 11, wherein a plurality of access points are formed at selected location on the cylindrical metallic sidewall.

14. The apparatus according to claim 13, wherein there are 4 access points.

15. The apparatus according to claim 1, wherein the housing is in the form of annular housing having a cylindrical metallic sidewall.

16. The apparatus according to claim 2, wherein the recording means is in the form of high fidelity camera.

17. The apparatus according to claim 2, the measuring mechanism is mounted at the periphery of the reaction chamber proximate to the first and third access point.

18. The apparatus according to claim 2, the means of emitting analytical beams is the form of electron gun.

19. The apparatus according to claim 2, the microscope is adjacently placed on the outside of the second access point of the reaction chamber.

20. The apparatus according to claim 2, further comprising an analytic instrument adjacently arranged at the outside of the fourth access point of the apparatus, the analytical instrument includes Raman spectroscope and XRD.

21. The apparatus according to claim 2, herein the substrate stage further comprising of an adjusting means for adjusting the position of the growth surfaces of the diamond seeds along axis of the annular housing.

22. The apparatus according to claim 21, wherein the adjustment means may in the form of actuator, step motor and the like.

23. A method of producing diamond and performing real time in situ analysis, comprising:
providing an apparatus according to claim 1,
placing a plurality of diamond seeds inside the reaction chamber, supplying hydrogen gas into the reaction chamber,
directing microwave emitted from the radiating means via the dielectric cover into the reaction chamber to form plasma discharge,
supplying mixture of reaction gases into the reaction chamber, growing the diamonds to a predetermined thickness,
recording the growth of the diamonds within the reaction chamber by the recording means via the dielectric cover,
measuring a set of predefined characteristics of the growth diamond layer, performing real time in situ analysis based on the measurement result, adjusting the process conditions according to the in situ analysis result, growing the diamond until a desirable thickness is achieved.

24. The method according to claim 23, wherein the plurality of diamond seeds is placed on a substrate in the reaction chamber.

25. The method according to claim 23, wherein the plurality of diamond seeds is placed onto a molybdenum substrate holder first before the molybdenum substrate holder is placed on the substrate holder.

26. A method for producing diamond under a predetermined set of nominal time-dependent process conditions and for performing real time measurements of the process conditions and diamond characteristics for real time in situ analysis, comprising the steps of:
placing a diamond seed on a substrate stage, the substrate stage mounted within a reaction chamber and movable relative to the reaction chamber;
introducing hydrogen into the reaction chamber;
directing microwave energy into the reaction chamber to form a plasma discharge;
introducing a mixture of reaction gases into the chamber while maintaining the plasma discharge to cause the diamond seed to grow on one or more diamond growth surfaces, the mixture including at least one gas containing carbon;
measuring the time-dependent process conditions in real time, the time-dependent process conditions including at least temperature, overall pressure, microwave power, relative amounts of reaction gases, and location of the substrate stage relative to the reaction chamber;
using an electron source to measure a crystalline structure of the one or more diamond growth surfaces;
adjusting the substrate stage during the growth of the one or more diamond growth surfaces such that electrons from the electron source continue to strike the one or more diamond growth surfaces; and
modifying the time-dependent process conditions in real time based on measurements of the time-dependent process conditions and measurements of the crystalline structure of one or more diamond growth surfaces.

27. The method of claim 26 further comprising the step of optically inspecting the plasma discharge.

28. The method of claim 26 further comprising the step of optically inspecting the one or more diamond growth surfaces.

29. The method of claim 27 further comprising the step of modifying the time-dependent process conditions in real time based on optical inspection of the plasma discharge.

30. The method of claim 28 further comprising the step of modifying the time-dependent process conditions in real time based on optical inspection of the one or more diamond growth surfaces.

31. The method of claim 26 wherein the electron source is a reflection high-energy electron diffraction (RHEED) device.

32. The method of claim 26 further including the step of using a Raman spectroscope to measure purity of the one or more diamond growth surfaces.

33. The method of claim 32 further comprising the step of modifying the time-dependent process conditions in real time based on the measured purity of the one or more diamond growth surfaces.

34. The method of claim 26 further including the step of using X-Ray diffraction (XRD) to measure purity of the one or more diamond growth surfaces.

35. The method of claim 34 further comprising the step of modifying the time-dependent process conditions in real time based on the measured purity of the one or more diamond growth surfaces.

36. The method of claim 26 wherein the mixture of reaction gases includes one or more of a hydrocarbonaceous gas, hydrogen gas, nitrogen gas, and gases containing other dopants.

37. The method of claim 26 wherein a fluidic coolant dissipates excessive heat generated by the plasma discharge so as to maintain the temperature in the reaction chamber within a suitable range.
